(19) United States
(12) Patent Application Publication
(10) Pub. No.: US 2016/0236245 A1
(43) Pub. Date: Aug. 18, 2016

(54) SELF-CLEANING SUBSTRATE CONTACT SURFACES

(71) Applicant: APPLIED MATERIALS, INC., Santa Clara, CA (US)

(72) Inventors: JEN SERN LEW, Singapore (SG); SRISKANTHARAJAH THIRUNAVUKARASU, Singapore (SG); Mukund SUNDARARAJAN, Bangalore (IN)

(21) Appl. No.: 14/620,781

(22) Filed: Feb. 12, 2015

(51) Int. Cl. B08B 6/00; H01L 21/687; H01L 21/02; H01L 21/683

(52) U.S. Cl. CPC B08B 6/00; H01L 21/6831; H01L 21/687; H01L 21/02057

(57) ABSTRACT

An apparatus for removing particles from a substrate contact surface includes parallel electrodes disposed beneath the substrate contact surface; and an alternating current (AC) power supply having a first AC terminal connected to a first parallel electrode and a second AC terminal connected to a second parallel electrode adjacent to the first parallel electrode, wherein an AC output of the first AC terminal has a different phase than an AC output of the second AC terminal. A method of removing particles from a substrate contact surface includes supplying a first alternating current (AC) to a first one of parallel electrodes disposed beneath the substrate contact surface; and supplying a second alternating current to a second one of the parallel electrodes disposed adjacent to the first parallel electrode; wherein the first alternating current has a different phase than the second alternating current.

### FIELD

Embodiments of the present disclosure generally relate to support surfaces of substrate supports and, more particularly, to removing particles from the support surfaces of the substrate supports.

### BACKGROUND

The presence of defects caused by particles in microelectronic devices or circuits formed on a substrate negatively impacts product yield. Particles may be generated by either chemical or mechanical sources. For example, during a deposition process, a film may be deposited on the inner surface of a process chamber which, in combination with repeated thermal cycling of the process chamber, may cause the film to delaminate and generate particles as well as cause flaking. As another example, mechanical abrasion with contact surfaces may also generate particles. The particle sizes of concern for manufacturing microelectronic devices or circuits may range from 50 nanometers and above.

Currently, defect reduction is directed at eliminating the defects caused by particles located at the front side of the substrate, namely, the side where dies are formed. However, the inventors have observed that particles are also often generated at the backside of the substrate because of contact with various system components during substrate handling and during chamber processing. For example, the substrate may be transferred into and out of a process chamber using a wand or an end effector of a robot, and the substrate may rest in the chamber on an electrostatic chuck or other substrate support, and over time, particles are generated at the substrate backside as a result of trapped residues and micro-scratches. The inventors have further observed that the generated particles may adhere to the surface of the substrate support, wand or end effector after contacting the substrate, and the adhered particles may be transferred to the back surface of a subsequently handled or processed substrate. The transferred particles may be carried with the subsequently processed substrates into other processing locations in a facility and become an unpredictable source of the particles that may negatively impact yield.

Accordingly, the inventors have provided herein a novel method and apparatus for a self-cleaning particle removal surface to avoid the above problem.

### SUMMARY

Apparatus and methods for removing particles from a substrate contact surface are provided herein. In some embodiments, an apparatus for removing particles from a substrate contact surface includes a plurality of parallel electrodes disposed beneath the substrate contact surface; and an alternating current (AC) power supply having a first AC terminal connected to a first one of the parallel electrodes and a second AC terminal connected to a second one of the parallel electrodes adjacent to the first one of the parallel electrodes, wherein an AC output of the first AC terminal has a different phase than an AC output of the second AC terminal.

In some embodiments, a substrate support includes parallel electrodes disposed beneath a support surface of the substrate support; and an alternating current (AC) power supply having a first AC terminal connected to a first one of the parallel electrodes, a second AC terminal connected to a second one of the parallel electrodes adjacent to the first one of the parallel electrodes, and a third AC terminal connected to a third one of the parallel electrodes adjacent to the first one of the parallel electrodes, wherein a phase difference between the AC outputs of any two of the first, second, and third AC terminals is 120°.

In some embodiments, a method of removing particles from a substrate contact surface includes supplying a first alternating current (AC) to a first one of a plurality of parallel electrodes disposed beneath the substrate contact surface; and supplying a second alternating current to a second one of the parallel electrodes disposed adjacent to the first one of the parallel electrodes; wherein the first alternating current has a different phase than the second alternating current.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic view of an electrodynamic screen in accordance with some embodiments of the present disclosure.

FIG. 2 depicts a schematic side view of a process chamber in accordance with some embodiments of the present disclosure.

FIGS. 3A and 3B respectively depict schematic side views of substrate holders in accordance with some embodiments of the present disclosure.

FIG. 4 depicts a schematic side view of a substrate in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure provide apparatus and methods for removing particles from a surface that comes in contact with a substrate, referred herein as a substrate contact surface. The substrate contact surface may be a surface of a substrate support or pedestal, a wand, an edge effector, or the like. Embodiments of the present disclosure may advantageously reduce contamination accumulated on a substrate contact surface during the manufacturing process, such as while the substrate is disposed on a substrate contact surface of a substrate support during a process or while the substrate is in contact with a substrate contact surface of a wand or edge effector that is handling the substrate between process steps, which can further limit or prevent contaminants from reaching the front-side of a substrate and causing device performance issues and/or yield loss. Embodiments of the present disclosure may be used in a wide variety of substrate contact surfaces that contact a substrate in processes where very low addition of particles is desired, for example, in display processing, silicon wafer processing, optics manufacturing, and the like.

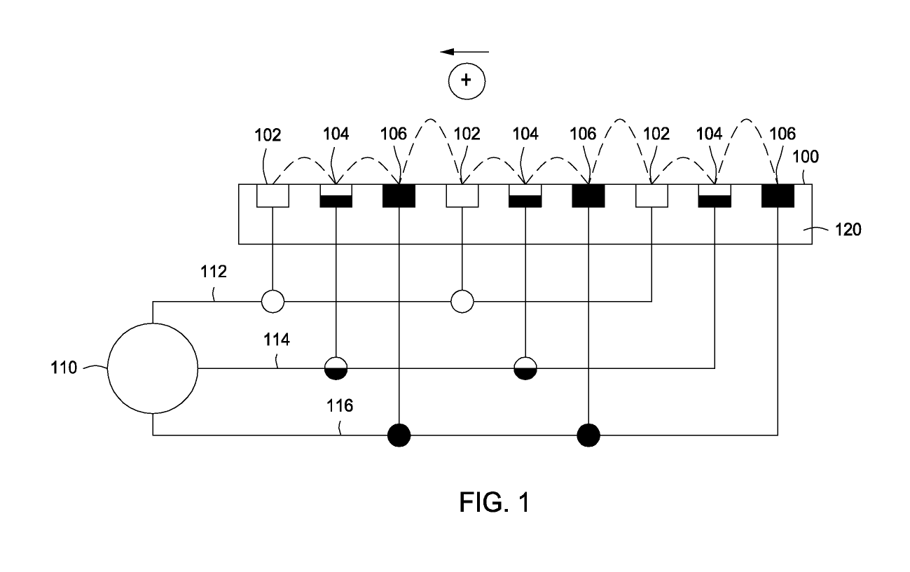

FIG. 1 illustrates an example of an electrodynamic screen and operation of the electrodynamic screen to remove particles from a substrate contact surface 100. A plurality of parallel electrodes 102, 104, 106 is embedded below the substrate contact surface 100 in a layer 120. The plurality of parallel electrodes 102, 104, 106 may be embedded adjacent to the substrate contact surface 100 or deeper within the layer 120. The spacing between electrodes may depend on the size of the particles that are to be removed and may depend on the diameter of the electrodes, and may depend on the voltage that may be applied to the electrodes, which may range from about 400 to about 3000 V. The layer 120 may be a polymer layer or of a screen printed material deposited atop a surface of a substrate support or pedestal, a wand, an edge effector, or the like, or the layer 120 may be part of the substrate support or pedestal, wand, or edge effector.

First parallel electrodes 102 are connected to a first terminal 112 of an alternating current (AC) power supply 110, and second parallel electrodes 104 are connected to a second terminal 114 of the AC power supply 110. The plurality of parallel electrodes 102, 104 may be arranged such that each one of the second parallel electrodes 104 is disposed adjacent to at least one of the first parallel electrodes 102. A two-phase or three-phase alternating current may then be provided to the plurality of parallel electrodes 102, 104 such that the first parallel electrodes 102 are at a different phase than the second parallel electrodes 104. For example, the first parallel electrodes 102 may be a half-cycle apart or one-third of a cycle apart from the second parallel electrodes 104.

Third parallel electrodes 106 may also be provided and are connected to a third terminal 116 of the AC power supply 110. The third parallel electrodes 106 may be arranged such that each of the third parallel electrodes 106 may be disposed, for example, between one of the first parallel electrodes 102 and one of the second parallel electrodes 104. A three-phase alternating current may then be provided such that the first parallel electrodes 102, the second parallel electrodes 104, and the third parallel electrodes 106 are each at different phases of an AC cycle. For example, each one of the first parallel electrodes 102 may be one-third of a cycle ahead of each one of the second parallel electrodes 104 and may be one-third of a cycle behind each one of the third parallel electrodes 106.

By driving the first parallel electrodes 102 and the second parallel electrodes 104 at different phases of the AC cycle, or by driving the first parallel electrodes 102, the second parallel electrodes 104, and the third parallel electrodes 106 at different phases of an AC cycle, the plurality of parallel electrodes generates a travelling electrostatic wave, also known as an electrodynamic screen or an electric curtain. When the AC cycle applies a maximum positive or negative voltage to the parallel electrode closest to the particle, the electric field generated induces an opposite charge on the side of the particle that faces that parallel electrode, namely, the electric field causes the particle to be electrically polarized. Then, when the polarity of the parallel electrode is reversed so that the charge on the electrode is the same as that of the facing side of the particle, the particle is repelled away from the parallel electrode and toward an adjacent parallel electrode that is at a 120 or 180 degree phase difference. When the AC cycle next drives the adjacent parallel electrode to have the same the polarity as the particle, the particle is repelled away from the adjacent parallel electrode and toward a further adjacent parallel electrode that is at a 120 or 180 degree phase difference from the adjacent parallel electrode. As the AC cycle repeats, the travelling wave of the maximum positive or negative voltage moves the particle along the parallel electrodes, i.e., along the substrate contact surface 100, until the particle is removed from the substrate contact surface 100. The frequency of the AC cycle may be sufficiently high enough, such as from about 5 to about 200 Hz, such that the particle is removed from the substrate contact surface 100 before the particle returns to an original, non-polarized state. The distance between, for example, the first parallel electrode 102 and the second parallel electrode 104 may be sufficiently small, such as from about 0.5 to about 2 mm, such that the particle is removed from the substrate contact surface 100 before the particle returns to an original, non-polarized state. The electrodynamic screen therefore advantageously provides a substrate contact surface 100 that is self-cleaning.

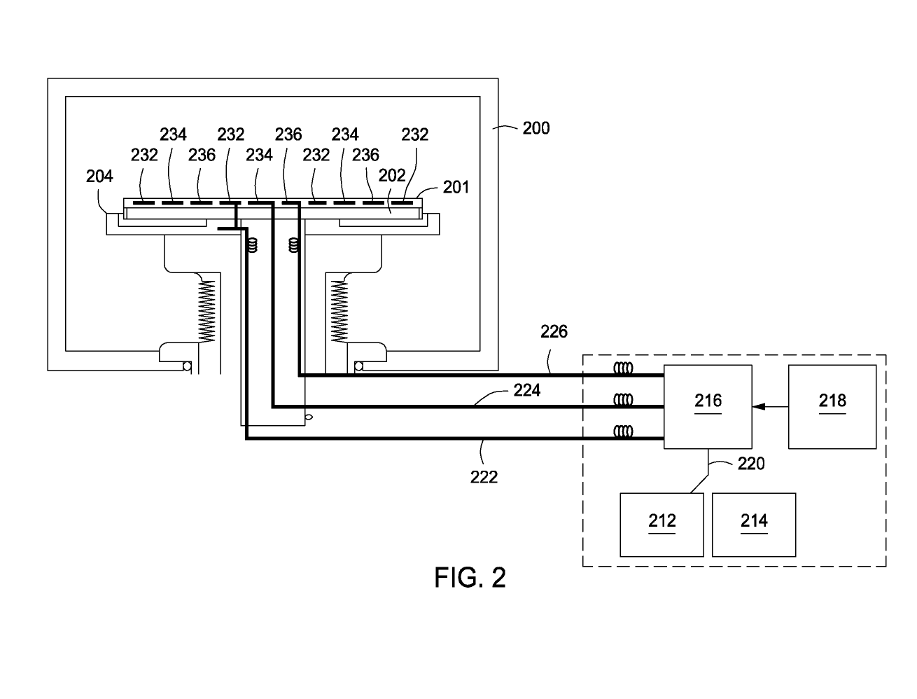

FIG. 2 illustrates an example of a deposition or etch chamber 200 in which first parallel electrodes 232, second parallel electrodes 234, and third parallel electrodes 236 are arranged within an upper layer 202 of a pedestal or substrate support 204 and driven in a manner similar to that of the first parallel electrodes 102, second parallel electrodes 104, and third parallel electrodes 106 depicted in FIG. 1.

An AC source 212, which may be a high voltage AC source, provides an AC voltage to the first parallel electrodes 232, second parallel electrodes 234, and third parallel electrodes 236. For example, each one of the first parallel electrodes 232 may be one-third of a cycle ahead of each one of the second parallel electrodes 234 and may be one-third of a cycle behind each one of the third parallel electrodes 236. The AC source 212 supplies power to the first parallel electrodes 232 through lead 222, supplies power to the second parallel electrodes 234 through lead 224, and supplies power to the third parallel electrodes 236 through lead 226.

Additionally, a direct current (DC) source 214, which may be a high voltage DC source, may provide a same DC clamping voltage to each one of the first parallel electrodes 232, second parallel electrodes 234, and third parallel electrodes 236 through each one of the leads 222, 224, and 226, respectively. A switch 220 selectively couples either an AC terminal of the AC source 212 or a DC terminal of the DC source 214 to the leads 222, 224, and 226 and may be driven by switching circuit 216 which is under the control of a user input 218. When the switch 220 connects the AC terminal of the AC source 212 to the leads 222, 224, and 226, the first parallel electrodes 232, second parallel electrodes 234, and third parallel electrodes 236 are driven to remove particle from atop the pedestal or substrate support 204 in a manner similar to that described regarding FIG. 1, and when the switch 220 connects the DC terminal of the DC source 214 to the leads 222, 224, and 226, a clamping voltage may be applied to the first parallel electrodes 232, second parallel electrodes 234, and third parallel electrodes 236.

By providing the capability of supplying an AC voltage or a DC voltage, the pedestal or substrate support 204 advantageously may operate as an electrostatic chuck or as an electrodynamic screen. For example, the electrostatic chuck may be used to secure a substrate during an etch or deposition process in the deposition or etch chamber 200 or to remove particles from substrate contact surface 201 atop pedestal or substrate support 204 surface during idle time of the deposition or etch chamber 200.

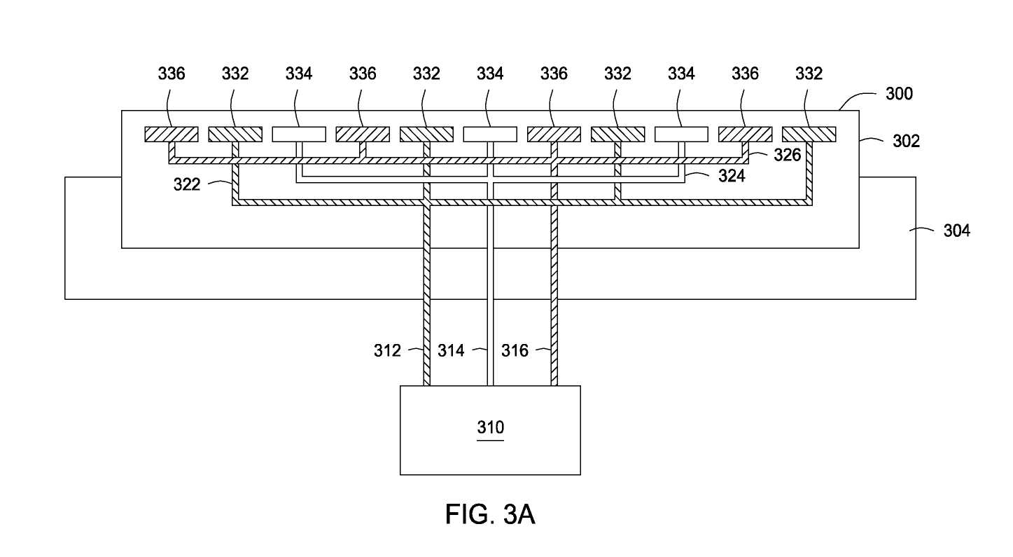

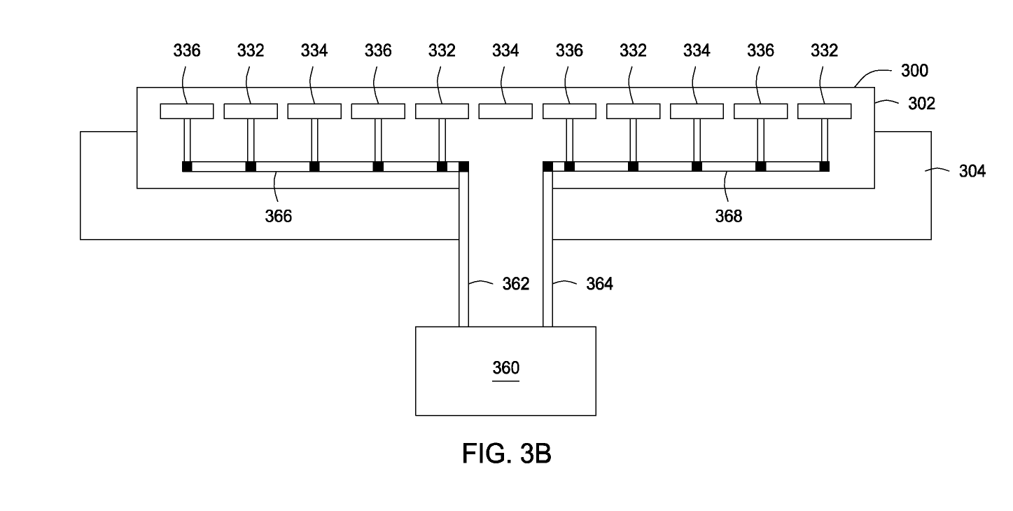

FIGS. 3A and 3B illustrate an example of wiring arrangements for alternately supplying an AC driving voltage or a DC clamping voltage to first parallel electrodes 332, second parallel electrodes 334, and third parallel electrodes 336. Though shown as separate figures, the wiring arrangement and power supplies shown in FIGS. 3A and 3B are both present in the pedestal or substrate support 304. As FIG. 3A shows, an AC power supply 310 may be connected to the first parallel electrodes 332, second parallel electrodes 334, and third parallel electrodes 336 through the leads 312, 314, and 316, respectively, to drive the first parallel electrodes 332, second parallel electrodes 334, and third parallel electrodes 336 to remove particles from the substrate contact surface 300 of a dielectric layer 302 of the pedestal or substrate support 304 in a manner similar to that described regarding FIG. 1. Alternatively, as FIG. 3B shows, a DC power supply 360 may supply a same DC clamping voltage to each one of to the first parallel electrodes 332, second parallel electrodes 334, and third parallel electrodes 336 through the leads 362 and 364 to provide monopolar clamping or may supply a first clamping voltage to one-half of the first parallel electrodes 332, second parallel electrodes 334, and third parallel electrodes 336 through the leads 362, 366 and may supply a second clamping voltage, of opposite polarity to first clamping voltage, to the other half of the first parallel electrodes 332, second parallel electrodes 334, and third parallel electrodes 336 through the leads 364, 368 to provide bipolar clamping. Thus, the same parallel electrodes may advantageously be used to remove particles from the substrate contact surface 300 or to clamp a substrate to the substrate contact surface 300.

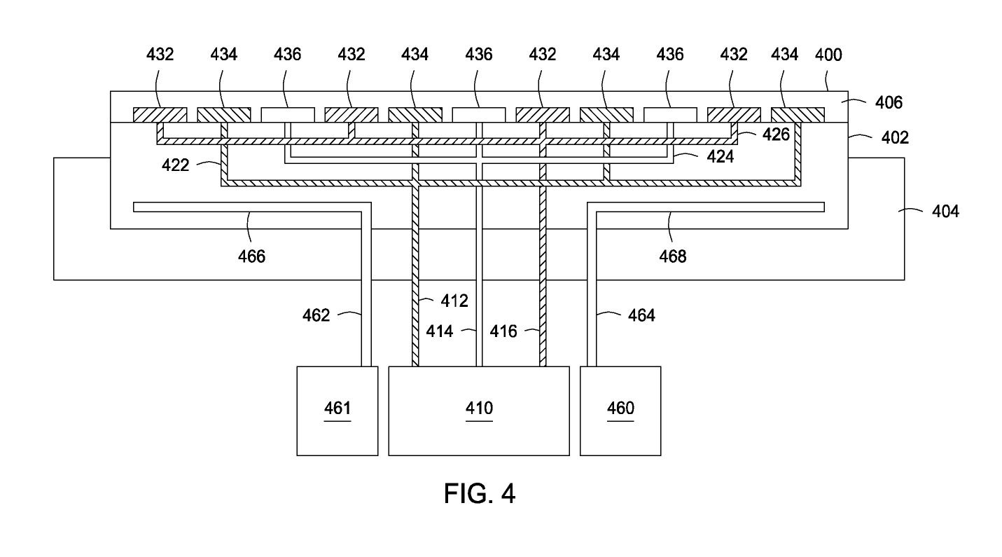

FIG. 4 illustrates another example of wiring arrangements for alternately supplying an AC driving voltage to a plurality of parallel electrodes disposed within a dielectric layer 402 of a pedestal or substrate support 404 or in an insulating layer 406 formed atop the dielectric layer 402 of the pedestal or substrate support 404. For example, an AC power supply 410 may supply AC power to the first parallel electrodes 432, second parallel electrodes 434, and third parallel electrodes 436 through the leads 412, 414, and 416, respectively, to drive the parallel electrodes to remove particles from a substrate contact surface 400 in a manner similar to that described regarding FIG. 1. Alternatively, DC power supplies 460, 461 may supply a same DC voltage to clamping electrodes 466 and 468 through leads 462 and 464, respectively, to provide monopolar clamping, or the DC power supplies 460, 461 may supply DC voltages of opposite polarity to the clamping electrodes 466 and 468, respectively, to provide bipolar clamping.

While the foregoing is directed to embodiments of the present disclosure, other and further embodiments of the disclosure may be devised without departing from the basic scope of the disclosure as described herein.

1. An apparatus for removing particles from a substrate contact surface, comprising:
a plurality of parallel electrodes disposed beneath the substrate contact surface; and
an alternating current (AC) power supply having a first AC terminal connected to a first one of the parallel electrodes and a second AC terminal connected to a second one of the parallel electrodes adjacent to the first one of the parallel electrodes, wherein an AC output of the first AC terminal has a different phase than an AC output of the second AC terminal.

2. The apparatus of the claim 1, wherein a phase difference between the AC outputs of the first and second AC terminals is 180°.

3. The apparatus of the claim 1, wherein the alternating current (AC) power supply includes a third AC terminal connected to a third one of the parallel electrodes adjacent to the first one of the parallel electrodes, and wherein a phase difference between the AC outputs of any two of the first, second, and third AC terminals is 120°.

4. The apparatus of the claim 1, further comprising:
a DC power supply having a DC terminal connected to at least one of the parallel electrodes.

5. The apparatus of the claim 4, wherein the at least one of the parallel electrodes is the first one of the parallel electrodes, and further comprising:
a switch to selectively couple the first one of the parallel electrodes to the DC terminal or the first AC terminal.

6. The apparatus of the claim 4, wherein the DC terminal is connected to each one of the parallel electrodes.

7. The apparatus of the claim 4, wherein the DC terminal is connected to the first one of the parallel electrodes, wherein the DC power supply includes a second DC terminal that is connected to the second one of the parallel electrodes, and wherein the DC terminal and the second DC terminal have different polarities.

8. The apparatus of the claim 1, wherein the substrate contact surface is a surface of a dielectric layer of a substrate support, and wherein the parallel electrodes are disposed within the dielectric layer.

9. The apparatus of the claim 1, wherein the substrate contact surface is a surface of an insulating layer disposed on a dielectric layer of a substrate support, wherein the parallel electrodes are disposed within the insulating layer, and wherein clamping electrodes are disposed within the dielectric layer.

10. The apparatus of the claim 1, wherein substrate contact surface is a surface of one of an electrostatic chuck, a wand, or an end effector.

11. The apparatus of the claim 1, wherein a distance between the first one of the parallel electrodes and the second one of the parallel electrodes is about 0.5 to about 2 mm.

12. The apparatus of the claim 1, wherein the AC power supply supplies alternating current having a voltage of about 400 to about 3,000 volts.

13. The apparatus of the claim 1, wherein the AC power supply supplies alternating current having a frequency of about 5 to about 200 Hz.

14. A substrate support, comprising:
parallel electrodes disposed beneath a support surface of the substrate support; and
an alternating current (AC) power supply having a first AC terminal connected to a first one of the parallel electrodes, a second AC terminal connected to a second one of the parallel electrodes adjacent to the first one of the parallel electrodes, and a third AC terminal connected to a third one of the parallel electrodes adjacent to the first one of the parallel electrodes, wherein a phase difference between outputs of any two of the first, second, and third AC terminals is 120°.

15. The substrate support of the claim 14, wherein the substrate support is an electrostatic chuck.

16. A method of removing particles from a substrate contact surface, comprising:
supplying a first alternating current (AC) to a first one of a plurality of parallel electrodes disposed beneath the substrate contact surface; and
supplying a second alternating current to a second one of the parallel electrodes disposed adjacent to the first one of the parallel electrodes; and
wherein the first alternating current has a different phase than the second alternating current.

17. The method of the claim 16, wherein a difference between the first alternating current and the second alternating current is 180°.

18. The method of the claim 16, further comprising:
supplying a third alternating current to a third one of parallel electrodes disposed adjacent to the first one of the parallel electrodes, wherein a phase difference between any two of the first alternating current, the second alternating current, and the third alternating current is 120°.

19. The method of the claim 16, wherein the alternating current is supplied at a voltage of about 400 to about 3,000 volts.

20. The method of the claim 16, wherein the alternating current is supplied at a frequency of about 5 to about 200 Hz.
